(19) United States
(12) Patent Application Publication
(10) Pub. No.: US 2026/0311779 A1
(43) Pub. Date: Oct. 8, 2026

(54) SEMICONDUCTOR DEVICE, OPERATING METHOD THEREOF, AND IN-MEMORY COMPUTING APPARATUS

(71) Applicant: CCSH Corporation, Wuhan (CN)

(72) Inventors: Lei Jin, Wuhan (CN); Zongliang Huo, Wuhan (CN); Yuanyuan Min, Wuhan (CN); Yu Zhang, Wuhan (CN); Xinran Li, Wuhan (CN); Wendong Wang, Wuhan (CN); Feng Xu, Wuhan (CN); Ziye Zhang, Wuhan (CN)

(73) Assignee: CCSH Corporation, Wuhan (CN)

(21) Appl. No.: 19/358,206

(22) Filed: Oct. 14, 2025

(30) Foreign Application Priority Data
Apr. 3, 2025 (CN) 202510421787.7

(51) Int. Cl. G11C 16/34; G11C 16/10; G11C 16/26

(52) U.S. Cl. CPC G11C 16/3459; G11C 16/102; G11C 16/26

(57) ABSTRACT

The present disclosure provides a semiconductor device, an operating method thereof, and an in-memory computing apparatus. The semiconductor device includes a memory cell array including a plurality of memory strings, wherein each memory string includes a plurality of memory cells connected in series; and a peripheral circuit coupled to the memory cell array through a plurality of word lines and a plurality of bit lines, wherein the plurality of word lines include at least one first word line and at least one second word line, and the peripheral circuit is configured to: perform a first program operation on a memory cell coupled with a first word line; after performing the first program operation, perform a first read operation to obtain a first current passing through a single memory string; and perform a second program operation on a memory cell coupled with the second word line.

### CROSS-REFERENCE TO RELATED APPLICATIONS

This application claims the benefit of priority to Chinese Application No. 202510421787.7, filed on Apr. 3, 2025, which is hereby incorporated by reference in its entirety.

### TECHNICAL FIELD

The present disclosure relates to the field of semiconductor technology, and particularly relates to, but not limited to, a semiconductor device, an operating method thereof, and an in-memory computing apparatus.

### BACKGROUND

In a classical Von Neumann computing architecture, a memory and a processor are separated, and data transmission is performed between the memory and the processor through a data bus. When performing a command, the processor first reads data from the memory, and after completing the processing, writes updated data back into the memory, so that frequent data migration brings a huge power consumption and a time overhead; in addition, due to a limited bandwidth of the memory, the processing speed of the processor is limited by the access speed of the memory, and the calculation performance is greatly affected. With the rise of applications such as big data and artificial intelligence (AI), the processing of massive data makes the bottleneck of the Von Neumann computing architecture become increasingly prominent.

### SUMMARY

According to one aspect of the present disclosure, a semiconductor device is provided. The semiconductor device may include a memory cell array including a plurality of memory strings. Each of the memory strings may include a plurality of memory cells connected in series. The semiconductor device may include a peripheral circuit coupled to the memory cell array through a plurality of word lines and a plurality of bit lines. The plurality of word lines may include at least one first word line and at least one second word line. The peripheral circuit may be configured to perform a first program operation on a memory cell coupled with the first word line. The peripheral circuit may be configured to after performing the first program operation, perform a first read operation to obtain a first current passing through a single memory string of the memory strings. The peripheral circuit may be configured to perform a second program operation on a memory cell coupled with the second word line.

In some implementations, the peripheral circuit may be configured to, in response to the first current passing through at least one of the memory strings greater than a preset value, perform the second program operation on the memory cell coupled with the second word line. In some implementations, the peripheral circuit may be configured to, after performing the second program operation, perform the first read operation again until the first current passing through each of the memory strings in the first read operation is less than or equal to the preset value.

In some implementations, the peripheral circuit may be configured to, in response to the first current passing through the at least one of the memory strings greater than the preset value, perform the second program operation on the memory cell coupled with the second word line and in the memory string with first current greater than the preset value. In some implementations, the peripheral circuit may be configured to perform a program inhibit operation on the memory cell coupled with the second word line and in the memory string with the first current less than or equal to the preset value.

In some implementations, the at least one second word line includes M second word lines. In some implementations, M may be an integer greater than 1. In some implementations, the peripheral circuit may be configured to, after performing the second program operation on the memory cell coupled with a j-th second word line of the second word lines and in the memory string with the first current greater than the preset value, perform the first read operation again, where 1 ≤ j ≤ M-1. In some implementations, the peripheral circuit may be configured to, in response to the first current passing through the at least one of the memory strings greater than the preset value, perform the second program operation on the memory cell coupled with a (j+1)-th second word line of the second word lines and in the memory string with first current greater than the preset value, and perform the first read operation again until the first current passing through each of the memory strings in the first read operation is less than or equal to the preset value.

In some implementations, the second program operation may include N sub-program operations, where N is an integer greater than 1. In some implementations, the peripheral circuit may be configured to, after performing an i-th sub-program operation of the sub-program operations on the memory cell coupled with the j-th second word line and in the memory string with first current greater than the preset value, perform the first read operation again, where 1 ≤ i ≤ N -1. In some implementations, the peripheral circuit may be configured to, in response to the first current passing through the at least one of the memory strings greater than the preset value, perform an (i+1)-th sub-program operation of the sub-program operations on the memory cell coupled with the j-th second word line and in the memory string with first current greater than the preset value, and perform the first read operation again. In some implementations, a voltage applied to the second word line in the (i+1)-th sub-program operation may be greater than a voltage applied to the second word line in the i-th sub-program operation. In some implementations, the peripheral circuit may be configured to, after performing a N-th second program operation on the memory cell coupled with the j-th second word line and performing the first read operation again, in response to the first current passing through the at least one of the memory strings greater than the preset value, perform a 1^{st} sub-program operation of the sub-program operations on the memory cell coupled with the (j+1)-th second word line and in the memory string with first current greater than the preset value.

In some implementations, a voltage applied to the j-th second word line when performing the second program operation on the memory cell coupled with the j-th second word line may be equal to a voltage applied to the (j+1)-th second word line when performing the second program operation on the memory cell coupled with the (j+1)-th second word line.

In some implementations, the peripheral circuit may be configured to apply a first voltage to the second word line for turning on the memory cell coupled with the second word line to perform the first read operation. In some implementations, the peripheral circuit may be configured to apply a second voltage to the second word line to perform a verify operation of the second program operation. In some implementations, the first voltage may be greater than the second voltage.

In some implementations, the plurality of word lines may further include at least one third word line. In some implementations, the peripheral circuit may be configured to apply a first voltage to the second word line in a first time period and apply a third voltage to the third word line in a second time period to obtain a first current passing through the memory string in the second time period. In some implementations, a start time of the second time period may be later than or the same as a start time of the first time period. In some implementations, the peripheral circuit may be configured to apply a fourth voltage to the first word line and the third word line for turning on the memory cells coupled to the first word line and the third word line to perform the second program operation. In some implementations, the fourth voltage may be greater than the third voltage.

In some implementations, the peripheral circuit may be configured to determine a voltage applied to the second word line in the second program operation based on the first current passing through the memory string in the first read operation.

In some implementations, a plurality of memory strings in a same column may be coupled to a same bit line. In some implementations, each of the memory strings may further include a select transistor. In some implementations, the peripheral circuit may be configured to perform the first program operation on the memory cell coupled to the first word line based on weight information. In some implementations, the peripheral circuit may be configured to, in response to the first current passing through each of the memory strings in the first read operation less than or equal to a preset value, perform a third read operation to control the select transistor of each of the memory strings to be turned off or turned on based on input data, and determine a second current output by the bit line. In some implementations, the peripheral circuit may be configured to determine analog calculation information based on the second current.

According to another aspect of the present disclosure a method of operating a semiconductor device is provided. The method may include performing a first program operation on a memory cell coupled with a first word line. The method may include, after performing the first program operation, performing a first read operation to obtain a first current passing through a single memory string of memory strings. The method may include performing a second program operation on a memory cell coupled with a second word line. The semiconductor device may include a memory cell array including a plurality of memory strings. Each of the memory strings may include a plurality of memory cells connected in series. The semiconductor device may include a peripheral circuit coupled to the memory cell array through a plurality of word lines and a plurality of bit lines. The plurality of word lines may include at least one first word line and at least one second word line.

In some implementations, the method may include performing, in response to the first current passing through at least one of the memory strings greater than a preset value, the second program operation on the memory cell coupled with the second word line. In some implementations, the method may include, after performing the second program operation, performing the first read operation again until the first current passing through each of the memory strings in the first read operation is less than or equal to the preset value.

In some implementations, the performing, in response to the first current passing through the at least one of the memory strings greater than the preset value, the second program operation on the memory cell coupled with the second word line may include, in response to the first current passing through the at least one of the memory strings greater than the preset value, performing the second program operation on the memory cell coupled with the second word line and in the memory string with first current greater than the preset value. In some implementations, the method may include performing a program inhibit operation on the memory cell coupled with the second word line and in the memory string with the first current less than or equal to the preset value.

In some implementations, the at least one second word line may include M second word lines. In some implementations, M may be an integer greater than 1. In some implementations, the method may include, after performing the second program operation on the memory cell coupled with a j-th second word line of the second word lines and in the memory string with the first current greater than the preset value, performing the first read operation again, where 1 ≤ j ≤ M-1. In some implementations, the method may include, in response to the first current passing through the at least one of the memory strings greater than the preset value, performing the second program operation on the memory cell coupled with a (j+1)-th second word line of the second word lines and in the memory string with first current greater than the preset value, and performing the first read operation again until the first current passing through each of the memory strings in the first read operation is less than or equal to the preset value.

In some implementations, the second program operation may include N sub-program operations, where N is an integer greater than 1. In some implementations, the method may include, after performing a i-th sub-program operation of the sub-program operations on the memory cell coupled with the j-th second word line and in the memory string with first current greater than the preset value, performing the first read operation again, where 1 ≤ i ≤ N -1. In some implementations, the method may include, in response to the first current passing through the at least one of the memory strings being greater than the preset value, performing an (i+1)-th sub-program operation of the sub-program operations on the memory cell coupled with the j-th second word line and in the memory string with first current greater than the preset value, and performing the first read operation again. In some implementations, a voltage applied to the second word line in the (i+1)-th sub-program operation may be greater than a voltage applied to the second word line in the i-th sub-program operation. In some implementations, the method may include, after performing a N-th second program operation on the memory cell coupled with the j-th second word line and performing the first read operation again, in response to the first current passing through the at least one of the memory strings greater than the preset value, performing a 1^{st} sub-program operation of the sub-program operations on the memory cell coupled with the (j+1)-th second word line and in the memory string with first current greater than the preset value.

In some implementations, a voltage applied to the j-th second word line when performing the second program operation on the memory cell coupled with the j-th second word line may be equal to a voltage applied to the (j+1)-th second word line when performing the second program operation on the memory cell coupled with the (j+1)-th second word line.

In some implementations, the method may include applying a first voltage to the second word line for turning on the memory cell coupled with the second word line to perform the first read operation. In some implementations, the method may include applying a second voltage to the second word line to perform a verify operation of the second program operation. In some implementations, the first voltage may be greater than the second voltage.

In some implementations, the plurality of word lines may further include at least one third word line. In some implementations, the method may include applying a first voltage to the second word line in a first time period and apply a third voltage to the third word line in a second time period to obtain a first current passing through the memory string in the second time period. In some implementations, a start time of the second time period may be later than or the same as a start time of the first time period. In some implementations, the method may include applying a fourth voltage to the first word line and the third word line for turning on the memory cells coupled to the first word line and the third word line to perform the second program operation. In some implementations, the fourth voltage may be greater than the third voltage.

In some implementations, the method may include determining a voltage applied to the second word line in the second program operation based on the first current passing through the memory string in the first read operation.

In some implementations, a plurality of memory strings in a same column may be coupled to a same bit line. In some implementations, each of the memory strings may further include a select transistor. In some implementations, the method may include performing the first program operation on the memory cell coupled to the first word line based on weight information. In some implementations, the method may include, in response to the first current passing through each of the memory strings in the first read operation less than or equal to a preset value, performing a third read operation to control the select transistor of each of the memory strings to be turned off or turned on based on input data, and determining a current output by the bit line. In some implementations, the method may include determining analog calculation information based on the current output by the bit line.

According to a further aspect of the present disclosure, an in-memory computing apparatus is provided. The in-memory computing apparatus may include a semiconductor device configured to perform a first calculation on weight information and input data to obtain analog calculation information. The semiconductor device may include a memory cell array including a plurality of memory strings. Each of the memory strings may include a plurality of memory cells connected in series. The semiconductor device may include a peripheral circuit coupled to the memory cell array through a plurality of word lines and a plurality of bit lines. The plurality of word lines may include at least one first word line and at least one second word line. The peripheral circuit may be configured to perform a first program operation on a memory cell coupled with the first word line. The peripheral circuit may be configured to, after performing the first program operation, perform a first read operation to obtain a first current passing through a single memory string of the memory strings. The peripheral circuit may be configured to perform a second program operation on a memory cell coupled with the second word line. The in-memory computing apparatus may include a processing circuit coupled to the semiconductor device and configured to determine a calculation result based on the analog calculation information.

In some implementations, the processing circuit may include an analog-to-digital conversion circuit coupled to the semiconductor device and configured to convert the analog calculation information into digital information. In some implementations, the processing circuit may include a data processing circuit coupled to the analog-to-digital conversion circuit and configured to perform a second calculation on the digital information to determine the calculation result.

In some implementations, the processing circuit may include a control circuit coupled to the semiconductor device and configured to control the semiconductor device to perform the first calculation.

In the implementations of the present disclosure, after performing the first program operation on the memory cell coupled to the first word line to input the weight information, the peripheral circuit performs the first read operation to obtain the first current passing through individual memory strings, and then performs the second program operation on the memory cell coupled to the second word line to compensate for the current difference between individual memory strings. In this way, the peripheral circuit can make the currents passing through individual memory strings as consistent as possible during in-memory computing, thereby improving the inference accuracy of the in-memory computing.

### BRIEF DESCRIPTION OF THE DRAWINGS

FIG. 1 is a schematic diagram of an exemplary in-memory computing apparatus provided by an implementation of the present disclosure;

FIG. 2 is a schematic diagram of an exemplary semiconductor device provided by an implementation of the present disclosure;

FIG. 3 is a schematic structural diagram of a three-dimensional (3D) NAND memory cell array provided by an implementation of the present disclosure;

FIG. 4 is a schematic structural diagram of a memory cell array including a plurality of memory planes provided by an implementation of the present disclosure;

FIG. 5 is a schematic cross-sectional view of an exemplary memory cell array including memory strings provided by an implementation of the present disclosure;

FIG. 6 is a schematic diagram of an exemplary peripheral circuit provided by an implementation of the present disclosure;

FIG. 7 is a first schematic diagram of a semiconductor device provided by an implementation of the present disclosure;

FIG. 8 is a second schematic diagram of a semiconductor device provided by an implementation of the present disclosure;

FIG. 9 is a first schematic diagram of threshold voltage distribution states of a memory cell provided by an implementation of the present disclosure;

FIG. 10 is a second schematic diagram of threshold voltage distribution states of a memory cell provided by an implementation of the present disclosure;

FIG. 11 is a first flowchart of operations of compensating a current of a target memory string provided by an implementation of the present disclosure;

FIG. 12 is a second flowchart of operations of compensating a current of a target memory string provided by an implementation of the present disclosure;

FIG. 13 is a first schematic diagram of voltage waveforms in a process of compensating current of a memory string provided by an implementation of the present disclosure;

FIG. 14 is a second schematic diagram of voltage waveforms in a process of compensating current of a memory string provided by an implementation of the present disclosure;

FIG. 15 is a flowchart of a method of operating a semiconductor device provided by an implementation of the present disclosure;

FIG. 16 is a perspective view of an in-memory computing apparatus provided by an implementation of the present disclosure; and

FIG. 17 is a schematic diagram of an exemplary system with an in-memory computing apparatus provided by an implementation of the present disclosure.

### DETAILED DESCRIPTION

Exemplary implementations of the present disclosure will be described in more detail below with reference to the accompanying drawings. Although exemplary implementations of the present disclosure are shown in the drawings, it should be understood that the present disclosure may be implemented in various forms and should not be limited by the specific implementations set forth herein. Rather, these implementations are provided so that the present disclosure can be more thoroughly understood, and the scope of the disclosure can be fully conveyed to those skilled in the art.

In the following description, numerous details are given in order to provide a more thorough understanding of the present disclosure. However, it will be apparent to those skilled in the art that the present disclosure may be practiced without one or more of these details. In other examples, to avoid confusion with the present disclosure, some technical features known in the art are not described; that is, not all the features of actual implementations are described herein, and well-known functions and structures are not described in detail.

In the drawings, a same reference number refers to a same element throughout.

It should be understood that spatial relationship terms such as “under,” “below,” “lower,” “beneath,” “above,” “upper,” and the like may be used herein for ease of description to describe one element or feature’s relationship to another element or feature shown in the figures. It should be appreciated that the spatial relationship terms are intended to include different orientations of the device in use and operation in addition to the orientations shown in the figures. For example, if a device in the figures is flipped, then an element or feature described as being “under” or “below” or “beneath” another element will be oriented “on” the other element or feature. Thus, the exemplary terms “below” and “under” can include both upper and lower orientations. The device may additionally be oriented (rotated 90 degrees or at other orientation) and the spatial description terms used herein are interpreted accordingly.

The term used herein is for the purpose of describing specific implementations only, and is not used as a limitation of the present disclosure. As used herein, the singular forms “a,” “an,” and “the” are also intended to include the plural forms unless the context clearly indicates otherwise. It should also be understood that the terms “comprising” and/or “including,” when used in this specification, determine the presence of stated features, integers, steps, operations, elements and/or components, but do not preclude the presence or addition of one or more other features, integers, steps, operations, elements, components and/or groups. As used herein, the term “and/or” comprises any and all combinations of related listed items.

In a classical Von Neumann computing architecture, a memory and a processor are separated, and data transmission is performed between the memory and the processor through a data bus. When performing a command, the processor first reads data from the memory, and after completing the processing, writes the updated data back into the memory, so that frequent data migration brings huge power consumption and time overhead; in addition, due to limited memory bandwidth, the processing speed of the processor is limited by the access speed of the memory, and the calculation performance is negatively impacted. With the rise of applications such as big data and artificial intelligence, the processing of massive quantities of data makes the bottleneck of Von Neumann computing architecture increasingly prominent. In order to solve the bottleneck of the classical Von Neumann computing architecture, an in-memory computing chip architecture emerges, and the basic idea thereof is to embed a computing function in a memory, and directly use the memory to perform logic computing, so that the data transmission amount and the transmission distance between the memory and the processor are reduced, the computing performance is improved while the power consumption is reduced, and therefore it is feasible to construct a computing system with a higher computing power, a higher bandwidth and a higher energy efficiency.

The in-memory computing chip has both storage capability and calculation capability by virtue of its own physical characteristics. The storage capability refers to the capability of different memories to store numerical values by changing their conductance values according to their physical characteristics, and the computing capability refers to the capability of completing vector-matrix multiplication calculation within a certain time according to Ohm’s law and Kirchhoff’s law by constructing an array composed of memory devices. The in-memory computing chip includes, but is not limited to, a static random access memory (SRAM), a NAND flash memory, and a dynamic random access memory (DRAM). The NAND flash memory is a non-volatile memory and has a larger capacity, so the NAND flash memory has become an object, which is given a wide attention, among the in-memory computing chips. Related content of the NAND flash memory will be described below.

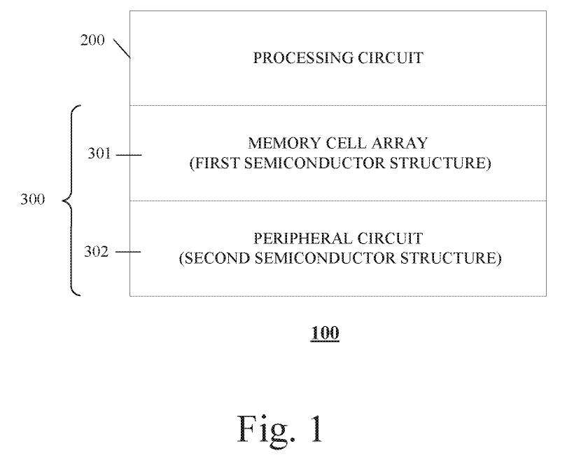

FIG. 1 is a schematic diagram of an exemplary in-memory computing apparatus 100 provided by an implementation of the present disclosure. The in-memory computing apparatus 100 includes a processing circuit 200 and a semiconductor device 300. The processing circuit 200 and the semiconductor device 300 may be connected by bonding, where the processing circuit 200 may include an analog-to-digital conversion circuit and a data processing circuit; the semiconductor device 300 may include a memory cell array 301 and at least a part of a peripheral circuit 302 coupled to the memory cell array 301; the analog-to-digital conversion circuit is configured to convert analog calculation information obtained by performing a calculation by the semiconductor device 300 into digital information; and the data processing circuit is configured to determine a calculation result based on the analog calculation information.

In some implementations, the processing circuit 200 and the semiconductor device 300 are in different planes and stacked on each other. Moreover, the memory cell array 301 and the peripheral circuit 302 in the semiconductor device 300 may be in different planes and stacked on each other, so that the planar size of the semiconductor device may be reduced.

In some implementations, the processing circuit 200 and the semiconductor device 300 may be formed in parallel on different substrates; for example, the processing circuit 200 is formed on a first substrate, the memory cell array 301 is formed on a second substrate, and the peripheral circuit 302 is formed on a third substrate. Then, the substrates are stacked on each other by using various bonding techniques such as hybrid bonding, transfer bonding, etc.

In the implementations of the present disclosure, by vertically integrating the processing circuit 200 and the semiconductor device 300, and vertically arranging the processing circuit 200, the memory cell array 301, and the peripheral circuit 302 into different planes, the chip size can be reduced, and the storage density can be increased.

In some implementations of the present disclosure, the semiconductor device 300 includes a first semiconductor structure formed with the memory cell array 301 and a second semiconductor structure formed with at least a portion of the peripheral circuit 302. In some implementations, a portion of the peripheral circuit is formed in the second semiconductor structure and another portion thereof is formed in the first semiconductor structure. In other words, the peripheral circuit may be divided into two portions, where one portion of the peripheral circuit and the memory cell array are formed together in the first semiconductor structure, and the other portion of the peripheral circuit is formed in the second semiconductor structure. For example, in the implementations of the present disclosure, the page buffer among the peripheral circuits may be formed in the first semiconductor structure.

In some other implementations, the peripheral circuit may be entirely formed in the second semiconductor structure. It should be noted that the implementations of the present disclosure are described by using an example in which the peripheral circuit is entirely formed in the second semiconductor structure.

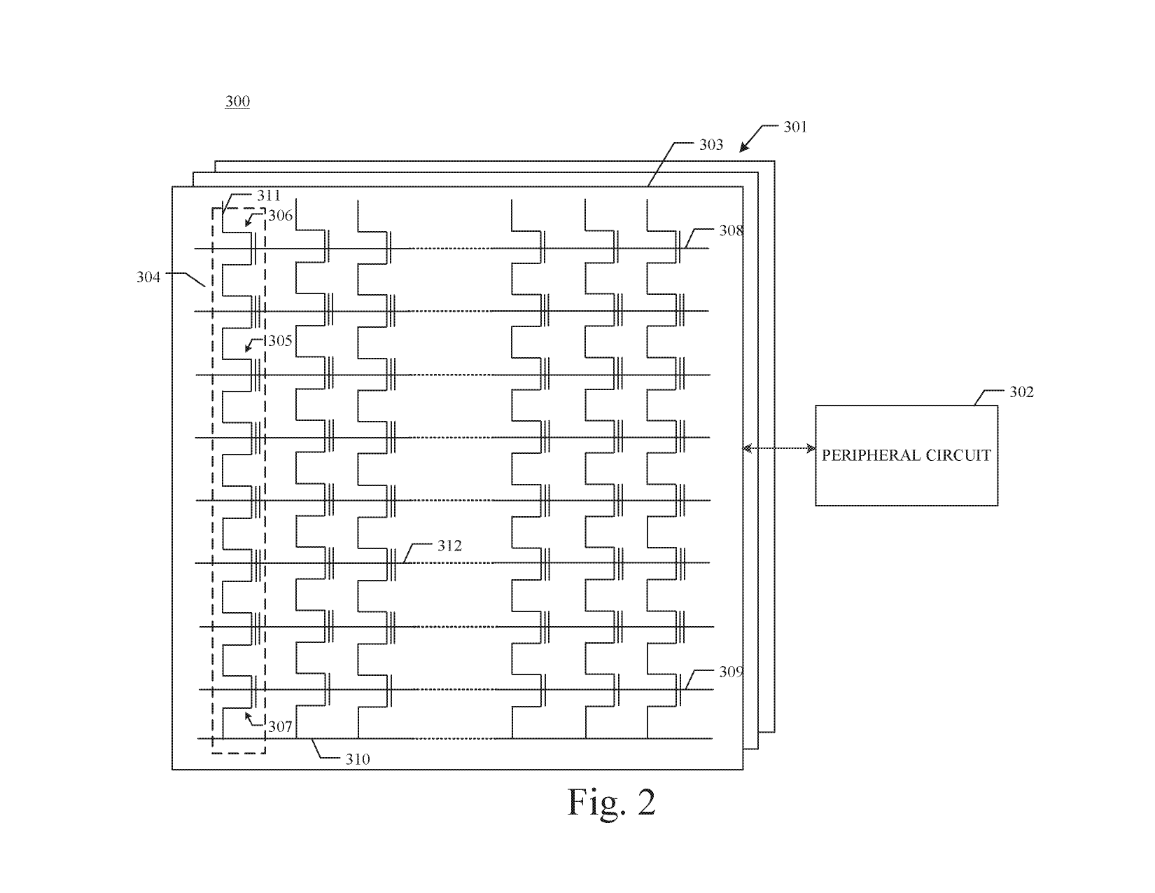

FIG. 2 is a schematic diagram of an exemplary semiconductor device 300 including a peripheral circuit 302 and a memory cell array 301 provided by an implementation of the present disclosure. The memory cell array 301 is described by using an example, in which the memory cell array 301 is a three-dimensional NAND memory cell array. Here, the memory cells 305 are NAND memory cells, the memory cells 305 are provided in the form of an array of memory strings 304, and each memory string 304 extends vertically above a substrate (not shown). In some implementations, each memory string 304 includes a plurality of memory cells 305 coupled in series and stacked vertically. Each memory cell 305 may hold a continuous analog value, e.g., voltage or charge, depending on the number of electrons trapped within a region of the memory cell 305. Each memory cell 305 may be a floating gate type memory cell including a floating gate transistor or a charge trapping type memory cell including a charge trapping transistor.

In some implementations, each memory cell 305 is a Single Level Cell (SLC) which has two possible memory states and thus can store one bit of data. For example, a first memory state “0” may correspond to a first voltage range and a second memory state “1” may correspond to a second voltage range. In some implementations, each memory cell 305 is a multi-level cell capable of storing more than a single bit of data in four or more memory states, such as a Multi-Level Cell (MLC) storing two bits per cell, a Triple Level Cell (TLC) storing three bits per cell, or a Quad-Level Cell (QLC) storing four bits per cell.

As shown in FIG. 2, each memory string 304 may include a bottom select transistor (BST) 307 at its source terminal and a top select transistor (TST) 306 at its drain terminal. The bottom select transistor 307 and the top select transistor 306 may be configured to activate a selected memory string 304 during read and program operations. In some implementations, the sources of the memory strings 304 in the same memory block 303 may be coupled by a common source line (CSL) 310. In other words, all the memory strings 304 in the same memory block 303 have a common source or an array common source (ACS). According to some implementations, the top select transistor 306 of each memory string 304 is coupled to a respective bit line (BL) 311 from which data may be read or written via an output bus (not shown). In some implementations, each memory string 304 is configured to be selected or deselected by applying a select voltage (e.g., a voltage above a threshold voltage of the top select transistor 306) or a deselect voltage (e.g., 0V) to a top select gate (TSG) of the respective top select transistor 306 through one or more top select lines (TSL) 308 and/or by applying a select voltage (e.g., a voltage above a threshold voltage of the bottom select transistor 307) or a deselect voltage (e.g., 0V) to a bottom select gate (BSG) of the respective bottom select transistor 307 through one or more bottom select lines (BSL) 309.

As shown in FIG. 2, the memory strings 304 may be organized into a plurality of memory blocks 303, each of which may have a common source line 310. In some implementations, each memory block 303 is a basic unit of data for an erase operation; that is, all memory cells 305 on the same memory block 303 are erased simultaneously. To erase memory cells 305 in a selected memory block, the common source lines 310 coupled to the selected memory block and unselected memory blocks on the same plane as the selected memory block may be biased with an erase voltage. It should be appreciated that in some examples, the erase operation may be performed at a half memory block level, at a quarter memory block level, or at a level having any suitable number of memory blocks or any suitable fraction of a memory block. The memory cells 305 of adjacent memory strings 304 may be coupled by a word line 312 that selects which row of memory cells 305 is affected by a read or program operation.

In some implementations, peripheral circuit 302 may include any suitable analog, digital, and mixed signal circuit for facilitating the operations of the memory cell array 301 by applying and sensing voltage signals and/or current signals to and from each target memory cell 305 through bit lines 311, word lines 312, common source lines 310, bottom select lines 309, and top select lines 308. Peripheral circuit 302 may include various types of peripheral circuits formed using metal-oxide-semiconductor technology.

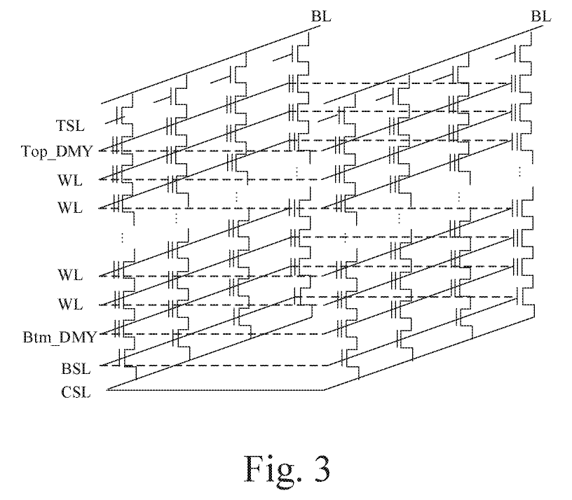

FIG. 3 is a schematic structural diagram of a three-dimensional NAND memory cell array provided by an implementation of the present disclosure, where the word line WL, the bit line BL, the common source line CSL, the bottom selection line BSL and the top selection line TSL may be understood with reference to the corresponding implementation in FIG. 2, and details thereof are not described herein again. In addition, the memory cell array may further include dummy word lines, for example, a top dummy word line Top_DMY and a bottom dummy word line Btm_DMY. It should be noted that the dummy word lines are not limited to be located at the top and the bottom of the memory cell array, and the dummy word lines may also be located in the middle area of the memory cell array.

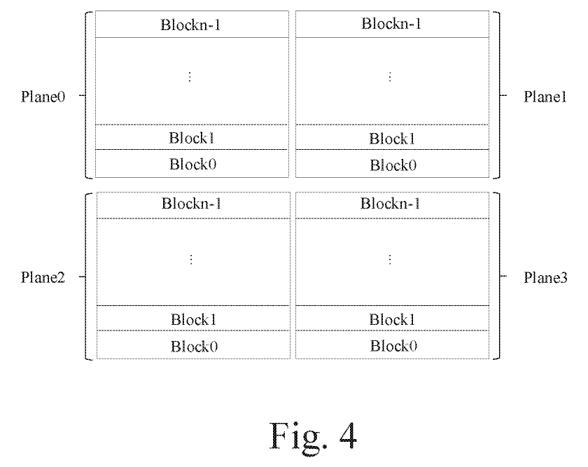

FIG. 4 is a schematic structural diagram of a memory cell array including a plurality of memory planes provided by an implementation of the present disclosure. Here, the memory cell array is described by using an example, in which the memory cell array is a three-dimensional NAND memory cell array. As shown in FIG. 4, the memory cell array may include a plurality of memory planes, for example, 4 memory planes, e.g., Plane0, Plane1, Plane2, and Plane3, and each memory plane may include a plurality of memory blocks, for example, n memory blocks Block0 to Blockn -1.

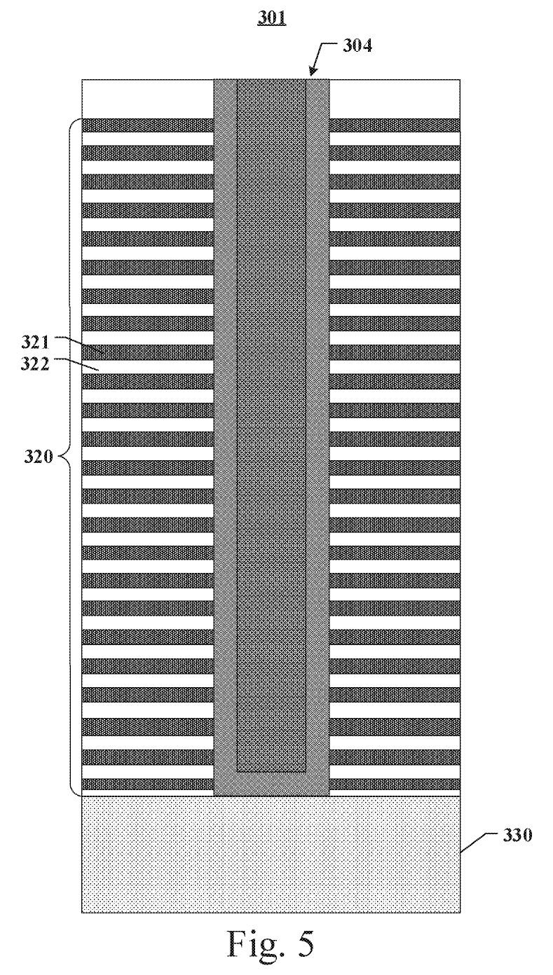

FIG. 5 is a schematic cross-sectional view of an exemplary memory cell array 301 including a memory string 304 provided by an implementation of the present disclosure. As shown in FIG. 5, the stacked structure 320 includes a plurality of gate layers 321 and a plurality of insulating layers 322 alternately stacked in sequence, as well as a memory string 304 vertically penetrating the gate layers 321 and the insulating layers 322. The gate layers 321 and the insulating layers 322 may be alternately stacked, and two adjacent gate layers 321 are separated by one insulating layer 322. The number of memory cells included in the memory cell array is mainly related to the number of pairs of gate layers 321 and insulating layers 322 in the stacked structure 320.

The gate layers 321 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 321 includes a metal layer, e.g., a tungsten layer. In some implementation, each gate layer 321 includes a doped-polysilicon layer. Each gate layer 321 may include a control gate surrounding the memory cell. The gate layer 321 at the top of the stacked structure 320 may extend laterally as a top select line, the gate layer 321 at the bottom of the stacked structure 320 may extend laterally as a bottom select line, and a gate layer 321 extending laterally between the top select line and the bottom select line may serve as a word line layer.

In some implementations, the stacked structure 320 may be disposed on the semiconductor layer 330. The semiconductor layer 330 may include silicon (e.g., monocrystalline silicon), silicon germanium (SiGe), gallium arsenide (GaAs), germanium (Ge), silicon-on-insulator (SOI), germanium-on-insulator (GOI), or any other suitable material. In some other implementations, the semiconductor device may not include the semiconductor layer.

In some implementations, the memory string 304 may include a channel structure extending vertically through the stacked structure 320. In some implementations, the channel structure includes a channel hole filled with semiconductor material(s) (e.g., as a semiconductor channel) and dielectric material(s) (e.g., as a memory film). In some implementations, the semiconductor channel includes silicon, e.g., polysilicon. In some implementations, the memory film is a composite dielectric layer including a tunneling layer, a storage layer (also referred to as a “charge trapping/storage layer”), and a barrier layer. The channel structure may have a cylindrical shape (e.g., a pillar shape).

According to some implementations, the semiconductor channel, the tunneling layer, the storage layer and the barrier layer are arranged in this order radially from the center of the pillar toward the outer surface of the pillar. The tunneling layer may include silicon oxide, silicon oxynitride, or any combination thereof. The storage layer may include silicon nitride, silicon oxynitride, or any combination thereof. The barrier layer may include silicon oxide, silicon oxynitride, a high dielectric constant (High-k) dielectric, or any combination thereof. In one example, the memory film may include a composite layer of silicon oxide/silicon oxynitride/silicon oxide (ONO).

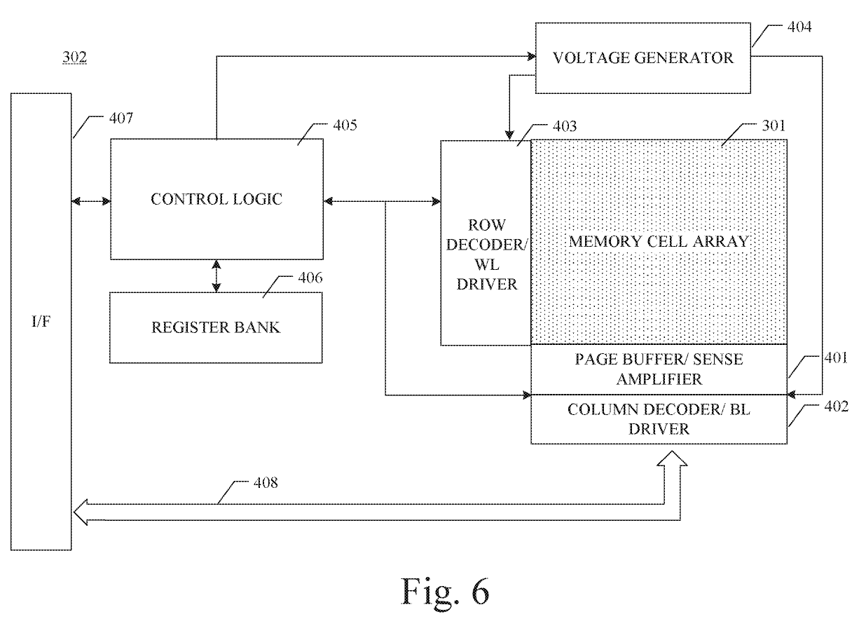

FIG. 6 illustrates some exemplary peripheral circuits 302 including a page buffer/sense amplifier 401, a column decoder/bit line driver 402, a row decoder/word line driver 403, a voltage generator 404, control logic 405, a register bank 406, a flash interface 407 (I/F), and a data bus 408. It should be understood that in some examples, additional peripheral circuits not shown in FIG. 6 may also be included. Peripheral circuit 302 may be coupled to memory cell array 301 through bit lines, word lines, source lines, BSL and TSL, etc.

Page buffer/sense amplifier 401 may be configured to read data from the memory cell array 301 and program (write) data to the memory cell array 301 according to control signals from control logic 405. In one example, the page buffer/sense amplifier 401 may store a page of program data (write data) to be programmed to the memory cell array 301. In another example, the page buffer/sense amplifier 401 may perform a program verify operation to ensure that data has been correctly programmed into memory cells coupled to the selected word line. In yet another example, the page buffer/sense amplifier 401 may also sense a low-power signal from a bit line representing a data bit stored in a memory cell and amplify a small voltage swing to an identifiable logic level in a read operation. Column decoder/bit line driver 402 may be configured to be controlled by the control logic 405 and to select one or more memory strings by applying a bit line voltage generated from voltage generator 404.

Row decoder/word line driver 403 may be configured to be controlled by the control logic 405 and select/deselect a memory block of the memory cell array 301 and select/deselect a word line for the memory block. The row decoder/word line driver 403 may also be configured to drive a word line using a word line voltage generated from the voltage generator 404. In some implementations, the row decoder/word line driver 403 may also select/deselect and drive a bottom select line and a top select line. As described in detail below, the row decoder/word line driver 403 is configured to perform a program operation on memory cells coupled to the selected word line(s). The voltage generator 404 may be configured to be controlled by the control logic 405 and generate word line voltages (e.g., read voltages, program voltages, pass voltages, local voltages, verify voltages, etc.), bit line voltages, and source line voltages to be supplied to the memory cell array 301.

Control logic 405 may be coupled to each peripheral circuit described above and configured to control the operation of each peripheral circuit. Register bank 406 may be coupled to control logic 405 and include status registers, command registers, and address registers for storing status information, command operation codes (OP codes), and command addresses for controlling operation of each peripheral circuit. Flash interface 407 may be coupled to control logic 405 and act as a control buffer to buffer and relay control commands received from a host-side device (not shown) to control logic 405 and to buffer and relay status information received from control logic 405 to a memory controller. Flash interface 407 may also be coupled to column decoder/bit line driver 402 via a data bus 408 and act as a data I/O interface and a data buffer to buffer and relay data to or from memory cell array 301.

In some implementations, referring to FIG. 1 to FIG. 3, the semiconductor device 300 may perform a first calculation on the weight information and the input data to obtain analog calculation information. For example, the peripheral circuit 302 may program the memory cells 305 coupled to each word line 312 based on the weight information, so that each memory cell 305 stores a respective calculation weight. For example, the plurality of memory cells 305 in the memory cell array 301 may be configured to store a weight matrix. The peripheral circuit 302 may further control the turning-on or turning-off of the top select transistor 306 in the corresponding memory string 304 based on the input data. For example, the value (“0” or “1”) of each bit of the input data may correspond to the turning-on or turning-off of the top select transistor 306 of one memory string 304. In this way, after the input data and the weight information are input into the memory cell array 301, the peripheral circuit 302 performs a read operation to determine a current passing through bit line 311 coupled to a plurality of memory strings 304; that is, the plurality of memory strings 304 coupled to the bit line 311 are operated in parallel, thereby achieving an addition calculation based on Kirchhoff’s law. Then, the peripheral circuit 302 determines analog calculation information based on the current passing through the bit line 311. For example, the sense amplifier 401 in the peripheral circuit 302 may be configured to convert the current output by the bit line 311 into analog calculation information. It should be noted that the threshold voltage distribution states of the memory cell 305 may include an erased state and at least one programmed state, and resistance values of the memory cell 305 at the erased state and the programmed states are different. Therefore, the memory cell 305 may be programmed to respective programmed states to store respective calculation weights.

The processing circuit 200 may determine a final calculation result based on the analog calculation information output by the semiconductor device 300, and the processing circuit 200 includes an analog-to-digital conversion circuit, a data processing circuit, and a control circuit. For example, the analog-to-digital conversion circuit may convert the received analog calculation information into digital information; the data processing circuit may perform a second calculation on the digital information to generate a calculation result (for example, the second calculation may include at least one of a compensation calculation, an activation calculation, a shift calculation, or a pooling calculation); and the control circuit may be configured to control the semiconductor device 300 to perform the first calculation (for example, the control circuit controls the semiconductor device 300 to perform operations such as programming, reading or the like on a corresponding memory cell).

It can be understood that the above addition calculation is implemented by parallel operations of multiple memory strings 304, and the larger the number of memory strings 304 coupled to one bit line 311, the higher the computing power. However, due to the different weights stored in individual memory strings 304, the difference in physical properties of individual memory strings 304 caused by the manufacturing process of the memory cell array 301, and the influence of factors such as the reliability of the semiconductor device 300, the currents passing through individual memory strings 304 may differ when the read operation is being performed to implement the addition calculation, and the current distribution is widened, which eventually leads to an accuracy decrease of the in-memory computing.

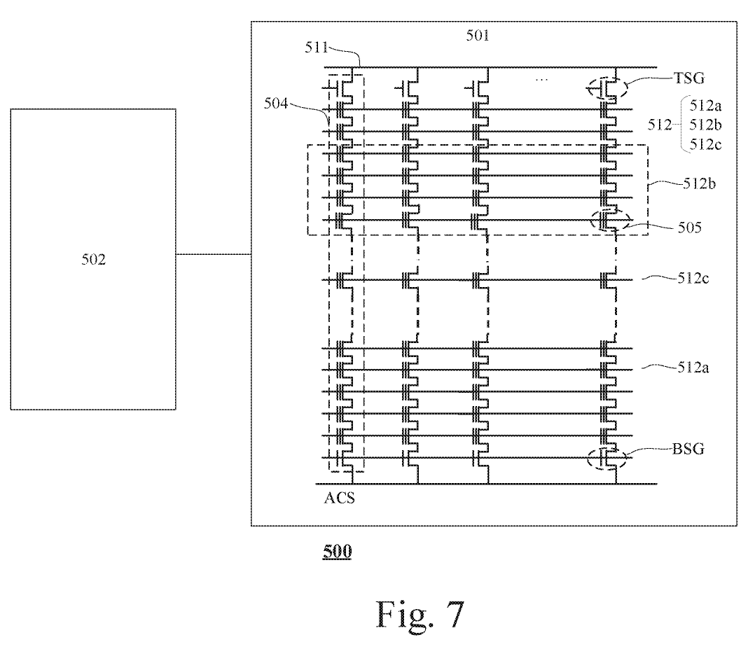

As shown in FIG. 7, an implementation of the present disclosure provides a semiconductor device 500, including: a memory cell array 501 including a plurality of memory strings 504, where each memory string 504 includes a plurality of memory cells 505 connected in series; and a peripheral circuit 502 coupled to the memory cell array 501 through a plurality of word lines 512 and a plurality of bit lines 511, where the plurality of word lines 512 include at least one first word line 512a and at least one second word line 512b, and the peripheral circuit 502 is configured to: perform a first program operation on memory cell 505 coupled to the first word line 512a; after performing the first program operation, perform a first read operation to obtain a first current passing through a single memory string 504; and perform a second program operation on memory cell 505 coupled with the second word line 512b.

In an implementation of the present disclosure, the semiconductor device 500 includes a memory cell array 501 and a peripheral circuit 502. Here, the memory cell array 501 is described by using an example, in which the memory cell array 501 is a three dimensional NAND type memory cell array. The memory cell array 501 and the peripheral circuit 502 may be respectively understood by reference to the memory cell array 301 and the peripheral circuit 302 in the foregoing implementations, and details thereof are not described herein again.

The plurality of memory cells 505 in the memory cell array 501 may be coupled to the peripheral circuit 502 by at least one first word line 512a and at least one second word line 512b. Memory cells 505 coupled with the first word line 512a may be configured to store the calculation weights, and memory cells 505 coupled with the second word line 512b may not be configured to store the calculation weights. The memory cells 505 coupled with the second word line 512b may be programmed to at least one programmed state, so as to compensate individual memory strings 504, so that the currents passing through individual memory strings 504 are as consistent as possible during the in-memory computing. In some implementations, the second word line 512b may be a dummy word line or a core word line.

For example, the peripheral circuit 502 may perform a first program operation on the plurality of memory cells 505 coupled to the first word line 512a based on the weight information, so that each memory cell 505 stores a corresponding calculation weight. After performing the first program operation, the peripheral circuit 502 may perform a first read operation to determine a first current passing through each memory string 504 one by one. In some implementations, the first read operation may include L sub-read operations respectively corresponding to L memory strings 504, and each sub-read operation is configured to determine a first current passing through one corresponding memory string 504, where L is a positive integer. In this way, the peripheral circuit 502 may perform a second program operation on the memory cell 505 coupled with the second word line 512b based on the first current passing through each memory string 504, making the first currents passing through each memory string 504 as consistent as possible, e.g., making the first current passing through each memory string 504 drop to almost the same current value. It should be noted that after the memory cell 505 is subjected to the program operation (such as the second program operation described above), the threshold voltage of the memory cell 505 increases, and the resistance value of the memory cell 505 itself increases, so that the first current passing through the corresponding memory string 504 decreases.

In an implementation of the present disclosure, after the peripheral circuit 502 performs the first program operation on the memory cell 505 coupled to the first word line 512a to input the weight information, the peripheral circuit 502 performs the first read operation to obtain the first current passing through individual memory strings 504, and then performs the second program operation on the memory cell 505 coupled to the second word line 512b to compensate for the current difference between individual memory strings 504. In this way, the peripheral circuit 502 can make the currents passing through individual memory strings 504 as consistent as possible during the in-memory computing, thereby improving the inference accuracy of the in-memory computing.

In some implementations, before performing the first program operation on the plurality of memory cells 505 coupled with the first word line 512a to input the weight information, the peripheral circuit 502 may further perform an erase operation on all the memory cells 505 coupled with the second word line 512b, so that all the memory cells 505 coupled with the second word line 512b are restored to an erased state.

In some implementations, for example, the peripheral circuit 502 is configured to: in response to the first current passing through at least one memory string 504 greater than a preset value, perform the second program operation on the memory cell 505 coupled with the second word line 512b; and after performing the second program operation, perform the first read operation again until the first current passing through each memory string 504 in the first read operation is less than or equal to the preset value.

In an implementation of the present disclosure, the peripheral circuit 502 performs the second program operation on the memory cell 505 coupled with the second word line 512b in a case where the first current passing through the at least one memory string 504 is greater than the preset value. For example, after performing the first program operation, the peripheral circuit 502 may perform the first read operation to determine the first current passing through each memory string 504 one by one, and then determine the memory string 504 with first current greater than a preset value, where the preset value may be determined according to actual design requirements and specifications (for example, 40 nA). In this way, the peripheral circuit 502 may perform the second program operation on the memory cell 505 coupled with the second word line 512b and in the memory string 504 with first current greater than the preset value in a case the first current passing through the at least one memory string 504 is greater than the preset value, so that the first current passing through each memory string 504 is finally close to the preset value; in other words, the currents passing through individual memory strings 504 are as consistent as possible.

After performing the second program operation on the memory cell 505 coupled with the second word line 512b, the peripheral circuit 502 may perform the first read operation again to determine a memory string 504, through which the first current greater than the preset value still passes, among one or more memory strings 504 corresponding to the memory cells 505 subjected to the second program operation. In this way, the peripheral circuit 502 may perform the second program operation again on the memory string 504, through which the first current greater than the preset value still passes, until the first current passing through each memory string 504 in the first read operation is less than or equal to the preset value. That is, the peripheral circuit 502 may repeatedly perform the second program operation and the first read operation, until the first current passing through each memory string 504 in the first read operation is less than or equal to the preset value; in other words, it is ensured that the currents passing through individual memory strings 504 are as consistent as possible, such that the inference accuracy of the in-memory calculation is improved.

In some implementations, the memory string 504 detected in each first read operation is a memory string 504 with first current greater than a preset value in a previous first read operation. For the memory string 504 whose first current has been less than or equal to the preset value in the previous first read operation, the second program operation and the first read operation do not need to be performed again, thereby improving in-memory calculation efficiency and saving energy consumption.

In some implementations, for example, the peripheral circuit 502 is configured to: in response to the first current passing through at least one memory string 504 greater than a preset value, perform the second program operation on the memory cell 505 coupled with the second word line 512b and in the memory string 504 with first current greater than the preset value, and perform a program inhibit operation on the memory cell 505 coupled with the second word line 512b and in the memory string 504 with first current less than or equal to the preset value.

In an implementation of the present disclosure, the peripheral circuit 502 may determine the first currents passing through individual memory strings 504 through the first read operation. In response to the first current passing through at least one memory string 504 greater than the preset value, the peripheral circuit 502 performs a second program operation on the memory cell 505 coupled with the second word line 512b and in the memory string 504 with first current greater than the preset value, thereby further reducing the first current passing through the memory string 504 with first current greater than the preset value; and the peripheral circuit 502 further performs a program inhibit operation on the memory cell 505 coupled with the second word line 512b and in the memory string 504 with first current less than or equal to the preset value, thereby preventing the first current passing through the memory string 504 with first current less than or equal to the preset value from further being reduced. In this way, after one or more cycles of the second program operation and the first read operation, the first current passing through each memory string 504 in the first read operation is less than or equal to the preset value; that is, it is ensured that the currents passing through individual memory strings 504 are as consistent as possible.

In some implementations, the word line 512 includes M second word lines 512b, where M is an integer greater than 1, and the peripheral circuit 502 is configured to: after performing the second program operation on the memory cell 505 coupled to the j-th second word line 512b and in the memory string 504 with the first current greater than the preset value, perform the first read operation again, where 1 ≤ j ≤ M-1; and in response to the first current passing through at least one memory string 504 greater than a preset value, perform the second program operation on the memory cell 505 coupled to the (j+1)-th second word line 512b and in the memory string 504 with first current greater than the preset value, and perform the first read operation again until the first current passing through each memory string 504 in the first read operation is less than or equal to the preset value.

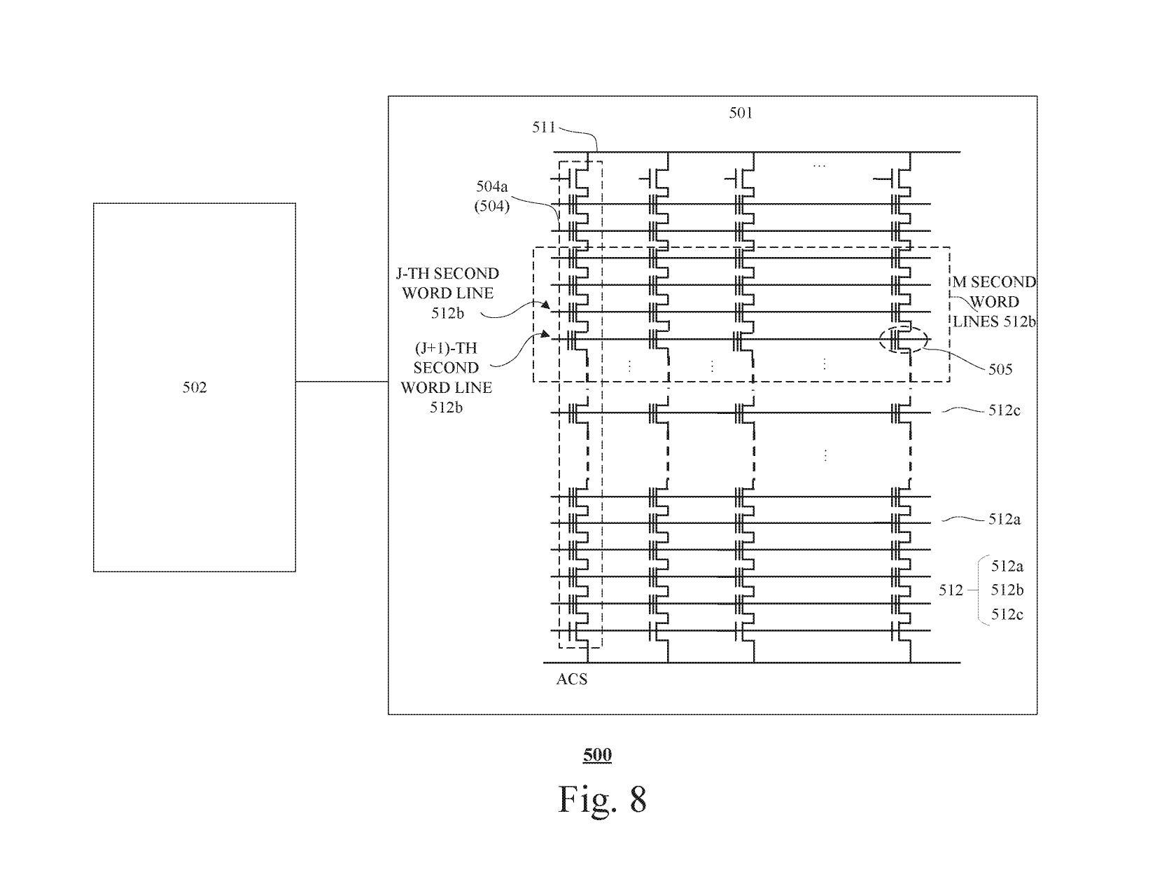

In an implementation of the present disclosure, as shown in FIG. 8, the word line 512 includes M second word lines 512b. After performing the first program operation, the peripheral circuit 502 may perform the first read operation to obtain the first currents passing through individual memory strings 504. When the first current passing through at least one memory string 504 is greater than the preset value, the peripheral circuit 502 performs the second program operation on the memory cell 505 coupled with the 1^{st} second word line 512b and in the target memory string 504a, so that the memory cell 505 coupled with the 1^{st} second word line 512b and in the target memory string 504a is transitioned from the erased state to the programmed state. It should be noted that the target memory string 504a herein refers to a memory string 504 for which all the first currents determined each time in the first read operation are greater than a preset value, and for ease of understanding, FIG. 8 only exemplarily shows one target memory string 504a, but more than one target memory string may be included without departing from the scope of the present disclosure.

After performing the second program operation on the memory cell 505 coupled with the 1^{st} second word line 512b, the peripheral circuit 502 may perform the first read operation again, and when there is still at least one memory string 504, through which the first current greater than the preset value passes, the peripheral circuit 502 may perform the second program operation on the memory cell 505 coupled with the 2^{nd} second word line 512b and in the target memory string 504a, so that the memory cell 505 coupled with the 2^{nd} second word line 512b and in the target memory string 504a is transitioned from the erased state to the programmed state. Through one or more cycles of the second program operation and the first read operation, the first current passing through each memory string 504 may be less than or equal to the preset value.

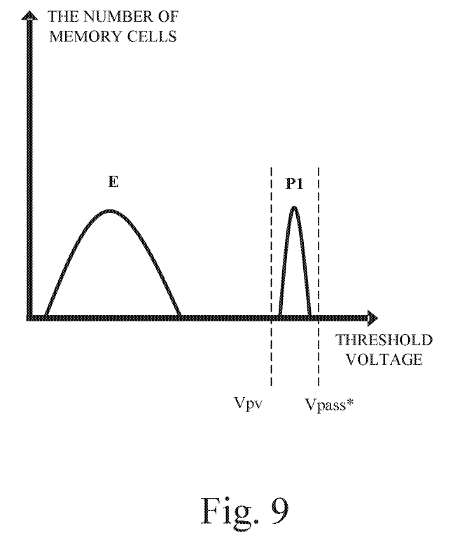

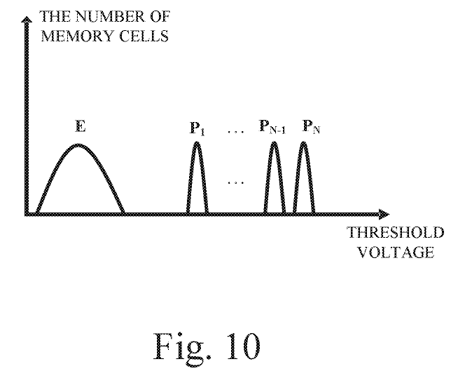

In some implementations, in a case where the memory cell coupled with the second word line is configured as SLC, referring to FIG. 9, the memory cell may be transitioned from the erased state E to the programmed state P1 through the second program operation. In the case where the memory cell coupled with the second word line is configured as MLC, TLC, QLC or more-level cell, referring to FIG. 10, the memory cell may be transitioned from the erased state E to the programmed state P1, P2,..., PN through the second program operation. It can be understood that the second program operation may include a plurality of sub-program operations, where each sub-program operation is configured to program the memory cell from a lower state to an adjacent higher state, such as E to P1, P1 to P2,..., P_{N-1} to P_{N}.

In some implementations, the second program operation may include a program operation and a program verify operation, and the program verify operation is configured to verify whether the memory cell is in the respective programmed state. In some other implementations, the second program operation may include only the program operation but does not the program verify operation; that is, the efficiency of the in-memory computing may be further improved by omitting the program verify operation.

In some implementations, after each program verify operation, a first read operation may also be performed, and subsequent program operations are stopped when the first currents on all memory strings are less than or equal to a preset value. That is, even if the memory cell is not programmed to the next programmed state, the subsequent programming can be stopped as long as the first current in the memory string reaches the preset value.

In some implementations, as shown in FIG. 8, the j-th second word line 512b and the (j+1)-th second word line 512b may be two physically adjacent second word lines 512b. For example, the j-th second word line 512b is located above the (j+1)-th second word line 512b in the vertical direction. In some other implementations, the j-th second word line and the (j+1)-th second word line may not be physically adjacent to each other, and actual positions and order of the 1^{st} to M-th second word lines in the memory cell array may be adjusted according to design requirements, which is not limited in the present disclosure.

In some implementations, a voltage applied to the j-th second word line when performing the second program operation on the memory cell coupled to the j-th second word line is equal to a voltage applied to the (j+1)-th second word line when performing the second program operation on the memory cell coupled to the (j+1)-th second word line.

In an implementation of the present disclosure, referring to FIG. 9, the memory cell coupled with the second word line may be configured as an SLC; that is, it includes two threshold voltage distribution states: an erased state E and a programmed state P1. Still referring to FIG. 8, after the second program operation is performed on the memory cell 505 coupled with a certain second word line 512b (e.g., the j-th second word line) so that this memory cell is transitioned from the erased state E to the programmed state P1), if there is still at least one memory string 504 with the first current greater than the preset value, the second program operation continues to be performed on the memory cell 505 coupled with the next second word line 512b (e.g., the (j+1)-th second word line). It can be understood that for any one second word line 512b, the second program operation programs the memory cell from the erased state E to the programmed state P1; therefore, the program voltages of any two second word lines 512b are the same; that is, the voltage applied to the j-th second word line when performing the second program operation on the memory cell coupled to the j-th second word line is equal to the voltage applied to the (j+1)-th second word line when performing the second program operation on the memory cell coupled to the (j+1)-th second word line.

In this way, the peripheral circuit does not need to program the memory cell to a programmed state higher than the programmed state P1, which is beneficial for reducing the operation time for compensating the current of the memory string, thereby improving the efficiency of the in-memory computing.

In some implementations, the second program operation includes N sub-program operations, where N is an integer greater than 1, and the peripheral circuit 502 is configured to: after performing a i-th sub-program operation of the sub-program operations on the memory cell coupled to the j-th second word line and in the memory string with first current greater than the preset value, perform the first read operation again, where 1 ≤ i ≤ N -1; in response to the first current passing through at least one memory string greater than a preset value, perform an (i+1)-th sub-program operation of the sub-program operations on the memory cell coupled to the j-th second word line and in the memory string with first current greater than the preset value, and perform the first read operation again, where a voltage applied to the second word line in the (i+1)-th sub-program operation is greater than a voltage applied to the second word line in the i-th sub-program operation; and after performing a N-th second program operation on the memory cell coupled to the j-th second word line and performing the first read operation again, in response to the first current passing through the at least one memory string greater than a preset value, perform a 1^{st} sub-program operation on the memory cell coupled to the (j+1)-th second word line and in the memory string with first current greater than the preset value.

In an implementation of the present disclosure, referring to FIG. 10, the memory cell coupled with the second word line may be configured as MLC, TLC, QLC or more-level cell, that is, it includes more than 2 threshold voltage distribution states: an erased state E, programmed states P1, P2..., P_{N}. In this case, the second program operation includes N sub-program operations, where a 1^{st} sub-program operation is configured to program the memory cell from the erased state E to the programmed state P1, a 2^{nd} sub-program operation is configured to program the memory cell from the programmed state P1 to the programmed state P2, a 3^{rd} sub-program operation is configured to program the memory cell from the programmed state P2 to the programmed state P3, and a N-th sub-program operation is configured to program the memory cell from the programmed state P_{N-1} to the programmed state P_{N}. It should be noted that the programmed states P1 shown in FIG. 10 and FIG. 9 may be different programmed states; that is, threshold voltage ranges of both are different.

After performing the first program operation, the peripheral circuit 502 may perform the first read operation to obtain the first current passing through each memory string 504. In response to the first current passing through the at least one memory string 504 greater than the preset value, the peripheral circuit 502 performs a 1^{st} sub-program operation on the memory cell 505 coupled with the 1^{st} second word line 512b and in the target memory string 504a, so that the memory cell 505 coupled with the 1^{st} second word line 512b and in the target memory string 504a is transitioned from the erased state E to the programmed state P1. After the 1^{st} sub-program operation, the peripheral circuit 502 performs the first read operation again, and in response to the first current passing through at least one memory string 504 greater than the preset value, the peripheral circuit 502 performs the 2^{nd} sub-program operation on the memory cell 505 coupled with the 1^{st} second word line 512b and in the target memory string 504a, so that the memory cell 505 coupled with the 1^{st} second word line 512b and in the target memory string 504a is transitioned from the programmed state P1 to the programmed state P2. In this way, if the first current passing through at least one the memory string 504 is still greater than the preset value after the N-th sub program operation is performed on the memory cell 505 coupled with the 1^{st} second word line 512b and in the target memory string 504a (e.g., the memory cell 505 coupled with the 1^{st} second word line 512b and in the target memory string 504a has been programmed to the highest programmed state P_{N}), then the peripheral circuit 502 can perform the 1^{st} sub program operation on the memory cell 505 coupled with the 2^{nd} second word line 512b and in the target memory string 504a. The above sub-program operation and the first read operation are cycled in this way, so that the first current passing through each memory string 504 is less than or equal to the preset value.

That is, in an implementation of the present disclosure, the 1^{st} sub-program operation (programming from the erased state E to the programmed state P1) may be first performed on the memory cell 505 coupled with a certain second word line 512b (the j-th second word line), and if there is still at least one memory string 504 with the first current greater than the preset value, then the 2^{nd} sub-program operation (programming from the programmed state P1 to the programmed state P2) may be performed on the memory cell 505 coupled with the second word line 512b (the j-th second word line),…, until the N-th sub-program operation (programming from the programmed state P_{N-1} to the programmed state P_{N} ) is performed on the memory cell 505 coupled with the second word line 512b (the j-th second word line). If there is still at least one memory string with the first current great then the preset value, then the 1^{st} sub program operation will continue to be performed on the next second word line 512b (the (j+1)-th second word line). Then, the 2^{nd} to N-th sub-program operations (assuming that the first current of at least one memory string in the first read operation after each sub-program operation is greater than the preset value) are repeatedly performed on the memory cell 505 coupled with the next second word line 512b (the (j+1)-th second word line) until the first current in the target memory string is less than or equal to the preset value.

It can be understood that since the 1^{st} sub-program operation to N-th sub-program operation are respectively configured to program the memory cell to the programmed state P1 to the programmed state PN, the program voltage applied to the second word line in the (i+1)-th sub-program operation is greater than the program voltage applied to the second word line in the i-th sub-program operation. Therefore, the current compensation precision of the memory string can be improved, and the inference accuracy of in-memory computing can be further improved.

In some implementations, the type of the memory cell may be configured according to actual design requirements. For example, the memory cell may be configured as SLC, MLC, TLC, QLC, etc., e.g., setting how many threshold voltage distribution states the memory cell will be programmed to in the second program operation, thereby meeting the requirements for the accuracy and efficiency of in-memory computing in different scenarios. It can be understood that the greater the number of memory-cell levels, the higher the current compensation precision of the memory string, and the higher the accuracy of in-memory computing; whereas the fewer the number of memory-cell levels, the faster the programming process in the current compensation of the memory string, and the higher the efficiency of in-memory computing.

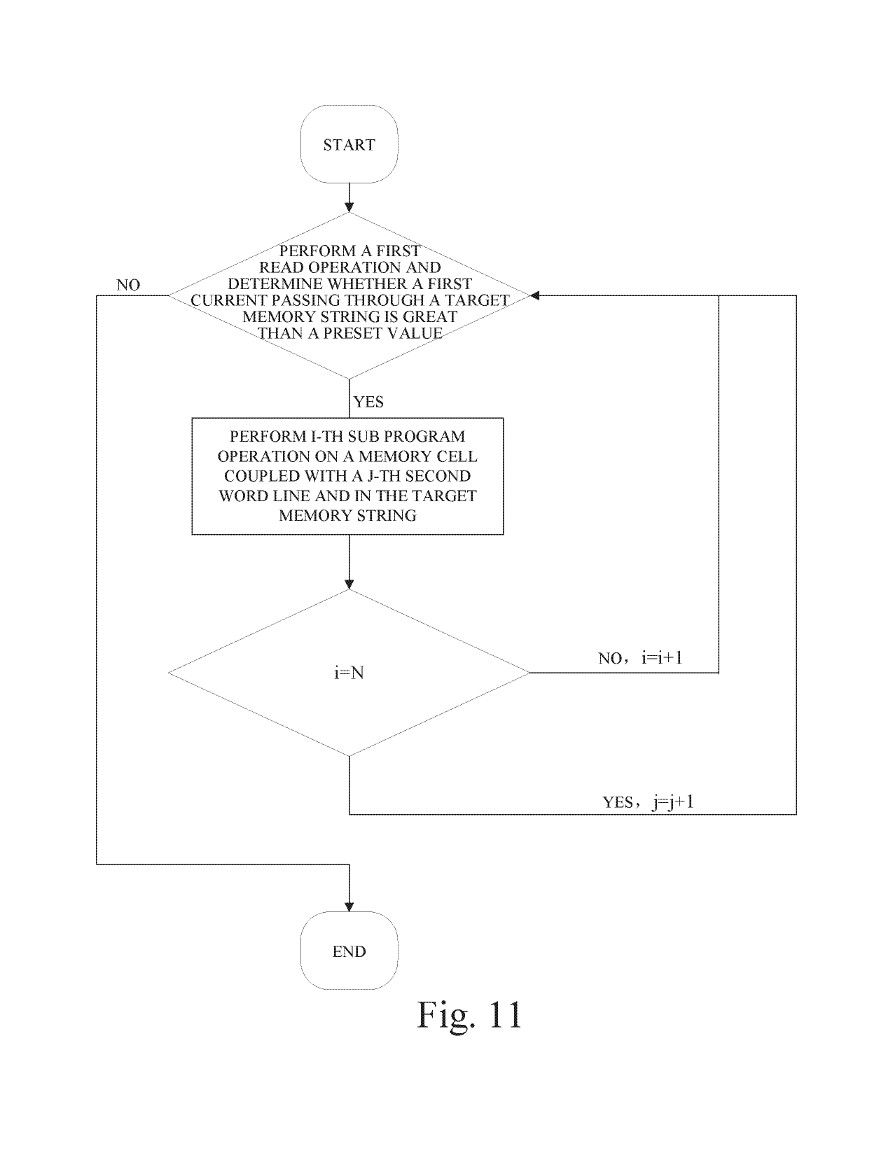

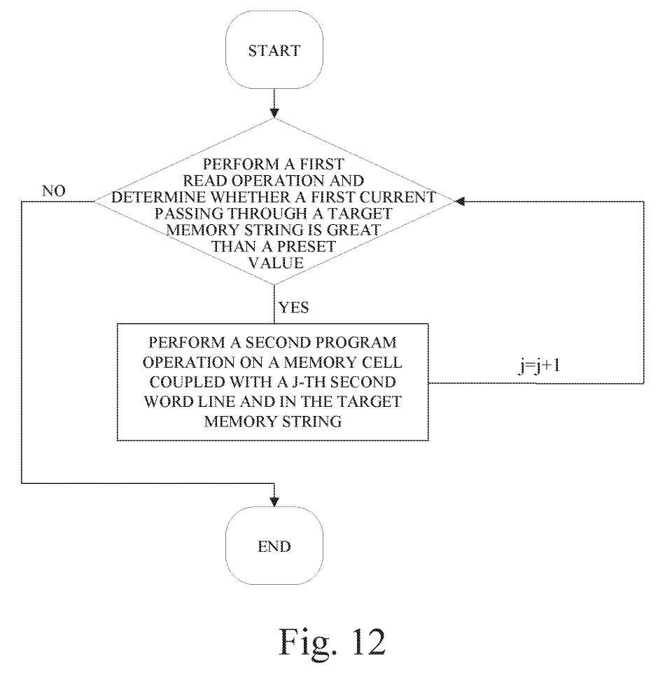

For ease of understanding, FIG. 11 and FIG. 12 respectively exemplarily show operations of compensating, by a peripheral circuit, the current of a target memory string in a case where the memory cell is configured as an MLC, a TLC, a QLC, or more-level cell, and in a case where the memory cell is configured as an SLC. The processes of FIG. 11 and FIG. 12 have been described in detail in foregoing implementations and will not be repeated herein.

In some implementations, for example, the peripheral circuit is configured to apply a first voltage Vpass* to the second word line to turn on the memory cell coupled with the second word line to perform the first read operation, and apply a second voltage Vpv to the second word line to perform a verify operation of the second program operation, where the first voltage is greater than the second voltage.

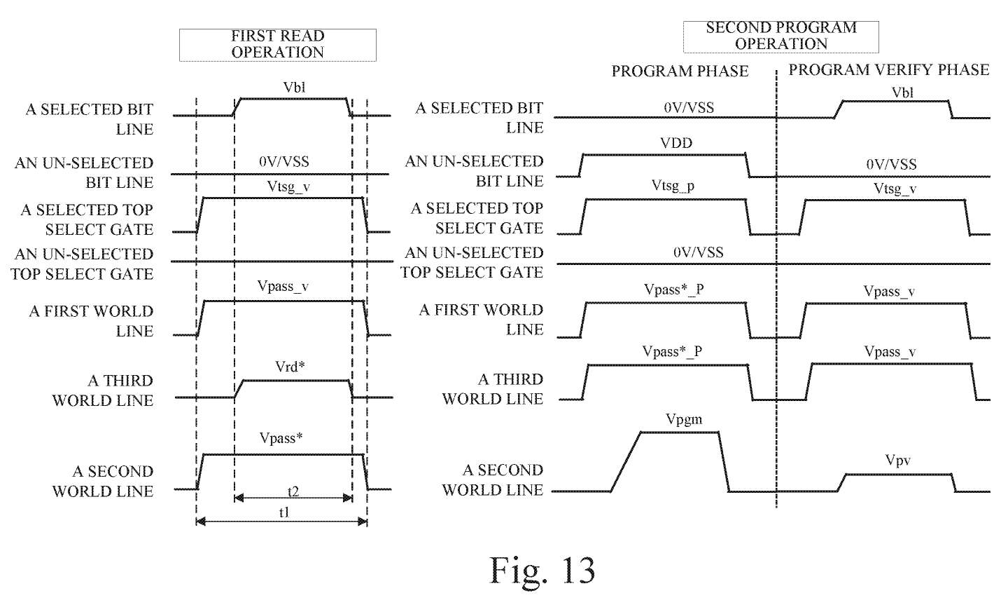

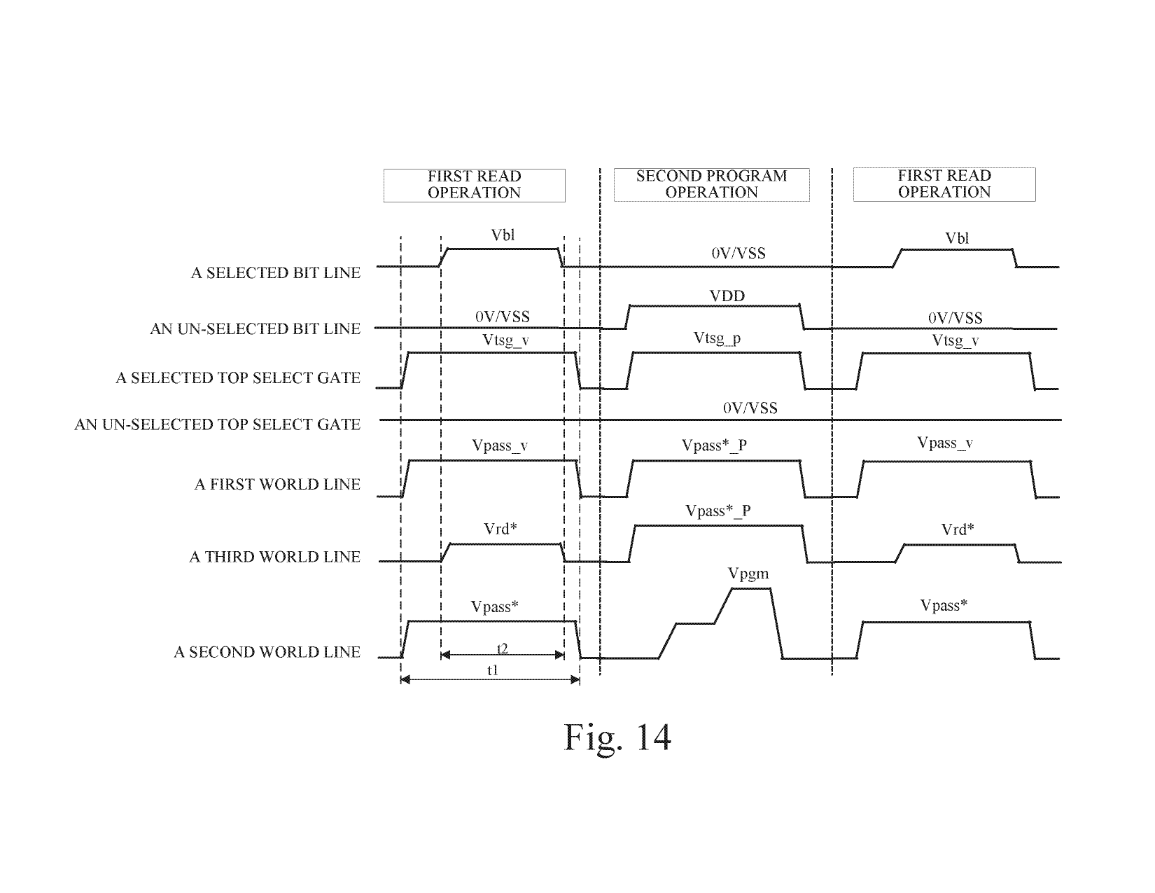

In an implementation of the present disclosure, FIG. 13 is a schematic diagram of a voltage waveform in a process of compensating a memory string current when a memory cell is configured as SLC, and FIG. 14 is a schematic diagram of a voltage waveform in a process of compensating a memory string current when a memory cell is configured as MLC, TLC, QLC or more-level cell. Referring to FIG. 13, the peripheral circuit may apply a first voltage Vpass* to the second word line for turning on the memory cell coupled with the second word line to perform a first read operation, so as to determine a first current passing through the corresponding memory string, where the first voltage Vpass* may be a pass voltage of the memory cell coupled with the second word line. The peripheral circuit may further apply a second voltage Vpv to the second word line to perform a verify operation of the second program operation, so as to determine whether the memory cell coupled with the second word line reaches the programmed state P1, where the second voltage Vpv may be a program verify voltage corresponding to the programmed state P1. It can be understood that, referring to FIG. 9, the first voltage Vpass* may be greater than the highest voltage of the programmed state P1 to turn on the corresponding memory cell, and the second voltage Vpv may be close to the lowest voltage of the programmed state P1, thereby measuring whether the memory cell reaches the 2^{nd} distribution state. Thus, the first voltage Vpass* as the pass voltage is greater than the second voltage Vpv as the program verify voltage. It should be noted that, for ease of understanding, FIG. 14 only shows a programming phase of the second program operation, but the second program operation may include a programming phase and a program verification phase.

In some implementations, as shown in FIGS. 7 and 8, the plurality of word lines 512 further include at least one third word line 512c, and the peripheral circuit 502 is configured to: apply a first voltage to the second word line 512b in a first time period, and apply a third voltage to the third word line 512c in a second time period to obtain a first current passing through the memory string in the second time period, where a start time of the second time period is later than a start time of the first time period, or the start time of the second time period is the same as the start time of the first time period; and apply a fourth voltage to the first word line 512a and the third word line 512c for turning on the memory cells 505 coupled to the first word line 512a and the third word line 512c to perform the second program operation, where the fourth voltage is greater than the third voltage.

In an implementation of the present disclosure, the peripheral circuit 502 may control the start of the first read operation by applying a corresponding pass voltage to the third word line 512c. For example, referring to FIG. 13 and FIG. 14, the peripheral circuit may apply a first voltage Vpass* to each second word line in the first time period t1 to turn on the memory cell coupled with each second word line and in the target memory string, and apply a same or different fifth voltage Vpass_v to each first word line to turn on the memory cell coupled with each first word line and in the target memory string (the fifth voltages Vpass_v applied to any two first word lines may be the same or different); and the peripheral circuit applies a third voltage Vrd* to the third word line in the second time period t2 to turn on the memory cell coupled to the third word line and in the target memory string, where all the memory cells in the entire target memory string are turned on in the second time period t2, and the peripheral circuit obtains the first current passing through the target memory string in the second time period t2. It can be understood that the start time of the second time period t2 is later than the start time of the first time period t1, or the start time of the second time period t2 is the same as the start time of the first time period t1, so that it can be ensured that the peripheral circuit starts to obtain the first current passing through the target memory string when the memory cell coupled with the third word line and in the target memory string is turned on.

In some implementations, the peripheral circuit may further apply a bit line read inhibit voltage (e.g., VSS or 0V) to the unselected bit lines in the first time period t1 to inhibit performing a first read operation on the unselected bit lines, apply a first turn-on voltage Vtsg_v to the selected top select gate in the first time period t1 to turn on the selected top select gate, and apply a turn-off voltage (e.g., VSS or 0V) to the unselected top select gates in the first time period t1 to turn off the unselected top select gates. The peripheral circuit may further apply a bit line read voltage Vbl to the selected bit line during the second time period t2 to obtain the first current passing through the target memory string via the selected bit line during the second time period t2.

In some implementations, referring to FIG. 13 and FIG. 14, the peripheral circuit may further apply a fourth voltage Vpass*_P to the first word line and the third word line to turn on the memory cell coupled to each of the first word line and third word line; apply a bit line program voltage (e.g., VSS or 0V) to the selected bit line, apply a bit line program inhibit voltage (e.g., VDD) to the unselected bit lines, apply a second turn-on voltage Vtsg_p to the selected top select gate to turn on the selected top select gate, and apply a turn-off voltage (e.g., VSS or 0V) to the unselected top select gates; and apply a program voltage Vpgm to the target second word line for performing the second program operation. It can be understood that the fourth voltage Vpass*_P is greater than the third voltage Vrd*, that is, the word line pass voltage is greater than the word line read voltage. Additionally, the fourth voltage Vpass*_P is also greater than or equal to the largest one of the plurality of different fifth voltages Vpass_v.

For example, the voltage generator in the peripheral circuit may be configured to generate a plurality of voltages including the first voltage, the second voltage, the third voltage, the fourth voltage, the fifth voltage, the first turn-on voltage, and the second turn-on voltage.

In some implementations, the foregoing program voltage Vpgm may be a stepped program voltage or have a fixed value, which is not limited in the present disclosure.

In some implementations, as shown in FIG. 7, the peripheral circuit 502 is further configured to determine a voltage to be applied to the second word line 512b in the second program operation based on the first current passing through the memory string 504 in the first read operation.

In an implementation of the present disclosure, in a case where the first current passing through the memory string 504 in the first read operation is greater than the preset value, the peripheral circuit 502 may further determine the program voltage (such as the program voltage Vpgm in the above implementations) to be applied to the second word line 512b in the second program operation according to the magnitude of the first current passing through the memory string 504 acquired in the first read operation. For example, if the difference between the first current passing through the memory string 504 and the preset value is large, the peripheral circuit 502 may set the voltage to be applied to the second word line 512b in the next second program operation to be large; otherwise, if the difference between the first current passing through the memory string 504 and the preset value is small, the peripheral circuit 502 may set the program voltage to be applied to the second word line 512b in the next second program operation to be small.

In some implementations, as shown in FIG. 7, a plurality of memory strings 504 located in a same column are coupled to a same bit line 511, each of the memory strings 504 further includes select transistors TSG/BSG, and the peripheral circuit 502 is further configured to: perform the first program operation on the memory cell 505 coupled with the first word line 512a based on weight information; in response to the first current passing through each memory string 504 in the first read operation less than or equal to the preset value, perform a third read operation to control the select transistor TSG of each memory string 504 to be turned off or turned on based on input data, and determine a second current output by the bit line 511; and determine analog calculation information based on the second current.

In the implementation of the present disclosure, the peripheral circuit 502 first programs the weight information into the corresponding memory cell 505 through the first program operation. Then, the peripheral circuit 502 compensates the currents of individual memory strings 504 by performing the first read operation and the second program operation, so that the currents passing through each memory string 504 are as consistent as possible. Then, the peripheral circuit 502 performs the third read operation, where the peripheral circuit 502 controls the turning-on or turning-off of the select transistor TSG/BSG in the corresponding memory string 504 based on the input data, and determines the second current output by the bit line 511, that is, implements the addition calculation based on Kirchhoff’s law; and finally, the peripheral circuit 502 determines the analog calculation information based on the second current output by the bit line 511.

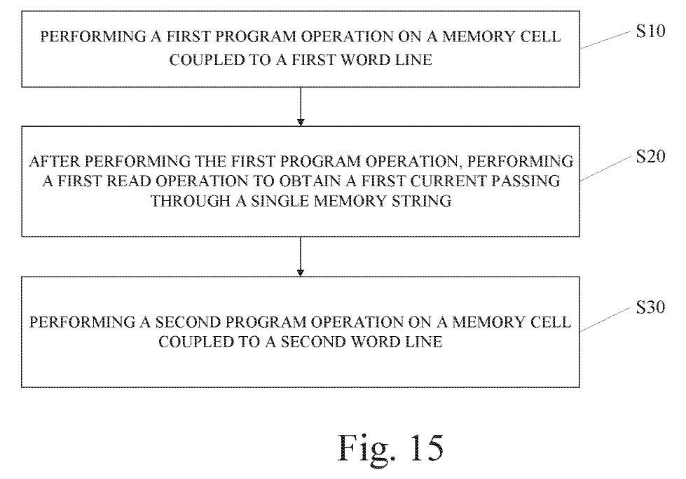

Based on the foregoing semiconductor device, an implementation of the present disclosure further provides a method of operating a semiconductor device, where the semiconductor device includes: a memory cell array including a plurality of memory strings, each of which includes a plurality of memory cells connected in series; and a peripheral circuit coupled to the memory cell array through a plurality of word lines and a plurality of bit lines, where the plurality of word lines include at least one first word line and at least one second word line; and as shown in FIG. 15, the method includes the following operations.

The method may include operation S10 of performing a first program operation on a memory cell coupled with the first word line; operation S20 of performing a first read operation to obtain a first current passing through a single memory string after performing the first program operation; and operation S30 of performing a second program operation on a memory cell coupled with the second word line.

It should be understood that the operations shown in FIG. 15 are not exclusive, and other operations may be performed before, after, or between any operations shown; and the order of the operations shown in FIG. 15 may be adjusted according to actual requirements.

In an implementation of the present disclosure, after performing the first program operation on the memory cell coupled to the first word line to input the weight information, the peripheral circuit performs the first read operation to obtain the first current passing through each memory string, and then performs the second program operation on the memory cell coupled to the second word line to compensate for the current difference between individual memory strings. In this way, the peripheral circuit can make the currents passing through the memory strings as consistent as possible in in-memory computing, thereby improving the inference accuracy of in-memory computing.

In some implementations, the method further includes: performing the second program operation on the memory cell coupled with the second word line in response to the first current passing through at least one memory string greater than a preset value; and after performing the second program operation, performing the first read operation again until the first current passing through each memory string in the first read operation is less than or equal to the preset value.

In some implementations, the performing the second program operation on the memory cell coupled with the second word line in response to the first current passing through at least one memory string greater than a preset value includes: in response to the first current passing through at least one memory string greater than a preset value, performing the second program operation on the memory cell coupled with the second word line and in the memory string with first current greater than the preset value. The method further includes: performing a program inhibit operation on the memory cell coupled with the second word line and in the memory string with the first current less than or equal to the preset value.

In some implementations, the at least one second word line includes M second word lines, where M is an integer greater than 1. For example, the method includes: after performing the second program operation on the memory cell coupled to the j-th second word line and in the memory string with the first current greater than the preset value, performing the first read operation again, where 1 ≤ j ≤ M-1; and in response to the first current passing through at least one memory string greater than a preset value, performing the second program operation on the memory cell coupled to the (j+1)-th second word line and in the memory string with first current greater than the preset value, and performing the first read operation again until the first current passing through each memory string in the first read operation is less than or equal to the preset value.

In some implementations, the second program operation includes N sub-program operations, where N is an integer greater than 1. For example, the method includes: after performing a i-th sub-program operation on the memory cell coupled to the j-th second word line and in the memory string with first current greater than the preset value, performing the first read operation again, where 1 ≤ i ≤ N -1; in response to the first current passing through at least one memory string greater than a preset value, performing an (i+1)-th sub-program operation on the memory cell coupled to the j-th second word line and in the memory string with first current greater than the preset value, and performing the first read operation again, where a voltage applied to the second word line in the (i+1)-th sub-program operation is greater than a voltage applied to the second word line in the i-th sub-program operation; and after performing a N-th second program operation on the memory cell coupled to the j-th second word line and performing the first read operation again, in response to the first current passing through the at least one memory string greater than a preset value, performing a 1^{st} sub-program operation on the memory cell coupled to the (j+1)-th second word line and in the memory string with first current greater than the preset value.

In some implementations, a voltage applied to the j-th second word line when performing the second program operation on the memory cell coupled to the j-th second word line is equal to a voltage applied to the (j+1)-th second word line when performing the second program operation on the memory cell coupled to the (j+1)-th second word line.

In some implementations, for example, the method includes: applying a first voltage to the second word line for turning on the memory cell coupled with the second word line to perform the first read operation; and applying a second voltage to the second word line to perform a verify operation of the second program operation, where the first voltage is greater than the second voltage.

In some implementations, the plurality of word lines further include at least one third word line. For example, the method includes: applying a first voltage to the second word line in a first time period and apply a third voltage to the third word line in a second time period to obtain a first current passing through the memory string in the second time period, where a start time of the second time period is later than a start time of the first time period, or the start time of the second time period is the same as the start time of the first time period; and applying a fourth voltage to the first word line and the third word line for turning on the memory cells coupled to the first word line and the third word line to perform the second program operation, where the fourth voltage is greater than the third voltage.

In some implementations, the method further includes: determining a voltage to be applied to the second word line in the second program operation based on the first current passing through the memory string in the first read operation.

In some implementations, a plurality of memory strings located in a same column are coupled to a same bit line, and each memory string further includes a select transistor. The method further includes: performing the first program operation on the memory cell coupled to the first word line based on weight information; in response to the first current passing through each memory string in the first read operation less than or equal to the preset value, performing a third read operation to control the select transistor of each memory string to be turned off or turned on based on input data, and determining a current output by the bit line; and determining analog calculation information based on the current output by the bit line.

The method of operating the semiconductor device as mentioned in the foregoing implementations has been described in detail in the foregoing implementations related to the semiconductor device, and will not be described herein again for brevity.

Based on the above semiconductor device, an implementation of the present disclosure further provides an in-memory computing apparatus, including: one or more semiconductor devices according to the above implementations, where the semiconductor device is configured to perform a first calculation on the weight information and the input data to obtain analog calculation information; and a processing circuit coupled to the semiconductor device, where the processing circuit is configured to determine a calculation result based on the analog calculation information.

In some implementations, the processing circuit includes an analog-to-digital conversion circuit coupled to the semiconductor device and configured to convert the analog calculation information into digital information; and a data processing circuit coupled to the analog-to-digital conversion circuit and configured to perform a second calculation on the digital information to determine the calculation result.

In some implementations, the processing circuit further includes a control circuit coupled to the semiconductor device and configured to control the semiconductor device to perform the first calculation.

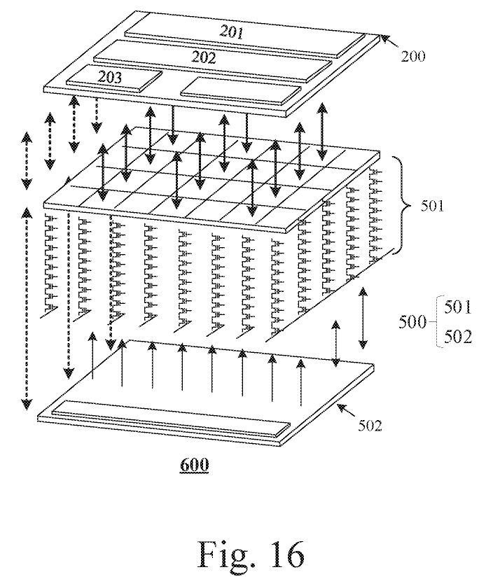

FIG. 16 is a perspective view of an in-memory computing apparatus 600 provided by the present disclosure. The in-memory computing apparatus 600 includes a semiconductor device 500 including a memory cell array 501 and a peripheral circuit 502, and a processing circuit 200 including an analog-to-digital conversion circuit 201, a data processing circuit 202, and a control circuit 203. Here, the processing circuit 200 and the semiconductor device 500 can be understood by reference to the above implementations and will not be repeated herein.

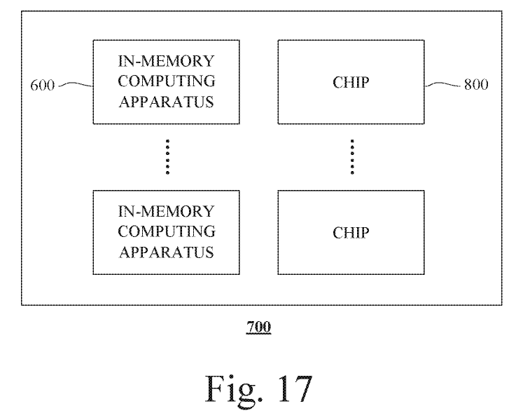

FIG. 17 is a schematic diagram of an exemplary system with an in-memory computing apparatus provided by the present disclosure. The system 700 may be a mobile phone, a desktop computer, a laptop computer, a tablet computer, a vehicle computer, a game console, a printer, a positioning device, a wearable electronic device, an intelligent sensor, a virtual reality (VR) device, an augmented reality (AR) device, or any other suitable electronic device having a storage apparatus therein. System 700 may include one or more in-memory computing apparatuses 600, and one or more chips 800 of other types. For example, the chip 800 includes, but is not limited to, a sensor chip, a memory chip, a logic chip, or the like. One or more in-memory computing apparatuses 600 and one or more chips 800 of other types may be integrated in a package, such as a Printed Circuit Board (PCB) package. As such, the system 700 may be applied to different scenarios.

The features disclosed in the several apparatus implementations provided by the present disclosure may be arbitrarily combined without conflict to obtain a new apparatus implementation.

The methods disclosed in the several method implementations provided by the present disclosure may be arbitrarily combined without conflict to obtain a new method implementation.

The above description is merely example implementations of the present disclosure, but the protection scope of the present disclosure is not limited thereto, and any person skilled in the art may easily conceive of changes or substitutions within the technical scope of the present disclosure, which shall fall within the protection scope of the present disclosure.

What is claimed is:

1. A semiconductor device, comprising:
a memory cell array comprising a plurality of memory strings, wherein each of the memory strings comprises a plurality of memory cells connected in series; and
a peripheral circuit coupled to the memory cell array through a plurality of word lines and a plurality of bit lines, wherein the plurality of word lines comprise at least one first word line and at least one second word line, and the peripheral circuit is configured to:
perform a first program operation on a memory cell coupled with the first word line;
after performing the first program operation, perform a first read operation to obtain a first current passing through a single memory string of the memory strings; and
perform a second program operation on a memory cell coupled with the second word line.

2. The semiconductor device of claim 1, wherein the peripheral circuit is configured to:
in response to the first current passing through at least one of the memory strings greater than a preset value, perform the second program operation on the memory cell coupled with the second word line; and
after performing the second program operation, perform the first read operation again until the first current passing through each of the memory strings in the first read operation is less than or equal to the preset value.

3. The semiconductor device of claim 2, wherein the peripheral circuit is configured to:
in response to the first current passing through the at least one of the memory strings greater than the preset value, perform the second program operation on the memory cell coupled with the second word line and in the memory string with first current greater than the preset value; and
perform a program inhibit operation on the memory cell coupled with the second word line and in the memory string with the first current less than or equal to the preset value.

4. The semiconductor device of claim 3, wherein:
the at least one second word line comprises M second word lines, wherein M is an integer greater than 1; and
the peripheral circuit is configured to:
after performing the second program operation on the memory cell coupled with a j-th second word line of the second word lines and in the memory string with the first current greater than the preset value, perform the first read operation again, wherein 1 ≤ j ≤ M-1; and
in response to the first current passing through the at least one of the memory strings greater than the preset value, perform the second program operation on the memory cell coupled with a (j+1)-th second word line of the second word lines and in the memory string with first current greater than the preset value, and perform the first read operation again until the first current passing through each of the memory strings in the first read operation is less than or equal to the preset value.

5. The semiconductor device of claim 4, wherein:
the second program operation comprises N sub-program operations, wherein N is an integer greater than 1; and
the peripheral circuit is configured to:
after performing a i-th sub-program operation of the sub-program operations on the memory cell coupled with the j-th second word line and in the memory string with first current greater than the preset value, perform the first read operation again, wherein 1 ≤ i ≤ N -1;
in response to the first current passing through the at least one of the memory strings greater than the preset value, perform an (i+1)-th sub-program operation of the sub-program operations on the memory cell coupled with the j-th second word line and in the memory string with first current greater than the preset value, and perform the first read operation again, wherein a voltage applied to the second word line in the (i+1)-th sub-program operation is greater than a voltage applied to the second word line in the i-th sub-program operation; and
after performing a N-th second program operation on the memory cell coupled with the j-th second word line and performing the first read operation again, in response to the first current passing through the at least one of the memory strings greater than the preset value, perform a 1^{st} sub-program operation of the sub-program operations on the memory cell coupled with the (j+1)-th second word line and in the memory string with first current greater than the preset value.

6. The semiconductor device of claim 4, wherein a voltage applied to the j-th second word line when performing the second program operation on the memory cell coupled with the j-th second word line is equal to a voltage applied to the (j+1)-th second word line when performing the second program operation on the memory cell coupled with the (j+1)-th second word line.

7. The semiconductor device of claim 1, wherein the peripheral circuit is configured to:
apply a first voltage to the second word line for turning on the memory cell coupled with the second word line to perform the first read operation; and
apply a second voltage to the second word line to perform a verify operation of the second program operation, wherein the first voltage is greater than the second voltage.

8. The semiconductor device of claim 1, wherein:
the plurality of word lines further comprise at least one third word line; and
the peripheral circuit is configured to:
apply a first voltage to the second word line in a first time period and apply a third voltage to the third word line in a second time period to obtain a first current passing through the memory string in the second time period, wherein a start time of the second time period is later than or the same as a start time of the first time period; and
apply a fourth voltage to the first word line and the third word line for turning on the memory cells coupled to the first word line and the third word line to perform the second program operation, wherein the fourth voltage is greater than the third voltage.

9. The semiconductor device of claim 1, wherein the peripheral circuit is further configured to:
determine a voltage applied to the second word line in the second program operation based on the first current passing through the memory string in the first read operation.

10. The semiconductor device of claim 1, wherein:
a plurality of memory strings in a same column are coupled to a same bit line;
each of the memory strings further comprises a select transistor; and
the peripheral circuit is further configured to:
perform the first program operation on the memory cell coupled to the first word line based on weight information;
in response to the first current passing through each of the memory strings in the first read operation less than or equal to a preset value, perform a third read operation to control the select transistor of each of the memory strings to be turned off or turned on based on input data, and determine a second current output by the bit line; and
determine analog calculation information based on the second current.

11. A method of operating a semiconductor device, comprising:
performing a first program operation on a memory cell coupled with a first word line;
after performing the first program operation, performing a first read operation to obtain a first current passing through a single memory string of memory strings; and
performing a second program operation on a memory cell coupled with a second word line,
wherein the semiconductor device comprises:
a memory cell array comprising a plurality of memory strings, wherein each of the memory strings comprises a plurality of memory cells connected in series; and
a peripheral circuit coupled to the memory cell array through a plurality of word lines and a plurality of bit lines, wherein the plurality of word lines comprise at least one first word line and at least one second word line.

12. The method of claim 11, further comprising:
performing, in response to the first current passing through at least one of the memory strings greater than a preset value, the second program operation on the memory cell coupled with the second word line; and
after performing the second program operation, performing the first read operation again until the first current passing through each of the memory strings in the first read operation is less than or equal to the preset value.

13. The method of claim 12, wherein the performing, in response to the first current passing through the at least one of the memory strings greater than the preset value, the second program operation on the memory cell coupled with the second word line comprises:
in response to the first current passing through the at least one of the memory strings greater than the preset value, performing the second program operation on the memory cell coupled with the second word line and in the memory string with first current greater than the preset value; and
the method further comprises:
performing a program inhibit operation on the memory cell coupled with the second word line and in the memory string with the first current less than or equal to the preset value.

14. The method of claim 13, wherein:
the at least one second word line comprises M second word lines, wherein M is an integer greater than 1; and
the method comprises:
after performing the second program operation on the memory cell coupled with a j-th second word line of the second word lines and in the memory string with the first current greater than the preset value, performing the first read operation again, wherein 1 ≤ j ≤ M-1; and
in response to the first current passing through the at least one of the memory strings greater than the preset value, performing the second program operation on the memory cell coupled with a (j+1)-th second word line of the second word lines and in the memory string with first current greater than the preset value, and performing the first read operation again until the first current passing through each of the memory strings in the first read operation is less than or equal to the preset value.

15. The method of claim 14, wherein:
the second program operation comprises N sub-program operations, wherein N is an integer greater than 1; and
the method comprises:
after performing a i-th sub-program operation of the sub-program operations on the memory cell coupled with the j-th second word line and in the memory string with first current greater than the preset value, performing the first read operation again, wherein 1 ≤ i ≤ N -1;
in response to the first current passing through the at least one of the memory strings being greater than the preset value, performing an (i+1)-th sub-program operation of the sub-program operations on the memory cell coupled with the j-th second word line and in the memory string with first current greater than the preset value, and performing the first read operation again, wherein a voltage applied to the second word line in the (i+1)-th sub-program operation is greater than a voltage applied to the second word line in the i-th sub-program operation; and
after performing a N-th second program operation on the memory cell coupled with the j-th second word line and performing the first read operation again, in response to the first current passing through the at least one of the memory strings greater than the preset value, performing a 1^{st} sub-program operation of the sub-program operations on the memory cell coupled with the (j+1)-th second word line and in the memory string with first current greater than the preset value.

16. The method of claim 14, wherein a voltage applied to the j-th second word line when performing the second program operation on the memory cell coupled with the j-th second word line is equal to a voltage applied to the (j+1)-th second word line when performing the second program operation on the memory cell coupled with the (j+1)-th second word line.

17. The method of claim 11, further comprising:
applying a first voltage to the second word line for turning on the memory cell coupled with the second word line to perform the first read operation; and
applying a second voltage to the second word line to perform a verify operation of the second program operation, wherein the first voltage is greater than the second voltage.

18. The method of claim 11, wherein:
the plurality of word lines further comprise at least one third word line; and
the method comprises:
applying a first voltage to the second word line in a first time period and apply a third voltage to the third word line in a second time period to obtain a first current passing through the memory string in the second time period, wherein a start time of the second time period is later than or the same as a start time of the first time period; and
applying a fourth voltage to the first word line and the third word line for turning on the memory cells coupled to the first word line and the third word line to perform the second program operation, wherein the fourth voltage is greater than the third voltage.

19. The method of claim 11, wherein:
a plurality of memory strings in a same column are coupled to a same bit line;
each of the memory strings further comprises a select transistor; and
the method further comprises:
performing the first program operation on the memory cell coupled to the first word line based on weight information;
in response to the first current passing through each of the memory strings in the first read operation less than or equal to a preset value, performing a third read operation to control the select transistor of each of the memory strings to be turned off or turned on based on input data, and determining a current output by the bit line; and
determining analog calculation information based on the current output by the bit line.

20. An in-memory computing apparatus, comprising:
a semiconductor device configured to perform a first calculation on weight information and input data to obtain analog calculation information, and comprising:
a memory cell array comprising a plurality of memory strings, wherein each of the memory strings comprises a plurality of memory cells connected in series; and
a peripheral circuit coupled to the memory cell array through a plurality of word lines and a plurality of bit lines, wherein the plurality of word lines comprise at least one first word line and at least one second word line, and the peripheral circuit is configured to:
perform a first program operation on a memory cell coupled with the first word line;
after performing the first program operation, perform a first read operation to obtain a first current passing through a single memory string of the memory strings; and
perform a second program operation on a memory cell coupled with the second word line; and
a processing circuit coupled to the semiconductor device and configured to determine a calculation result based on the analog calculation information.
